(19) United States
(12) Patent Application Publication
(10) Pub. No.: US 2026/0135523 A1
(43) Pub. Date: May 14, 2026

(54) OPERATIONAL AMPLIFIER CIRCUIT

(71) Applicant: Panasonic Automotive Systems Co., Ltd., Kanagawa (JP)

(72) Inventors: Makoto TAKEMOTO, Kanagawa (JP); Yoshimichi OOYA, Fukushima (JP); Yuki SAWADA, Kanagawa (JP)

(73) Assignee: Panasonic Automotive Systems Co., Ltd., Kanagawa (JP)

(21) Appl. No.: 19/377,628

(22) Filed: Nov. 3, 2025

(30) Foreign Application Priority Data
Nov. 8, 2024 (JP) 2024-196167

(51) Int. Cl. H03F 1/56; H03F 3/45

(52) U.S. Cl. CPC H03F 1/56; H03F 3/45475; H03F 2200/165

(57) ABSTRACT

An operational amplifier circuit includes a reference voltage generation circuit and a plurality of operational amplifier circuit sections. The reference voltage generation circuit is connected to a single power supply. The reference voltage generation circuit generates a reference voltage signal and outputs the reference voltage signal. Each of the operational amplifier circuit sections includes an operational amplifier that operates with the single power supply. An output impedance of the reference voltage generation circuit is set to cause a voltage fluctuation amount of the reference voltage signal to be equal to or less than a predetermined value.

### CROSS-REFERENCE TO RELATED APPLICATIONS

This application is based upon and claims the benefit of priority from Japanese Patent Application No. 2024-196167, filed on Nov. 8, 2024, the entire contents of which are incorporated herein by reference.

### FIELD

Embodiments of the present disclosure relate generally to an operational amplifier circuit.

### BACKGROUND

An operational amplifier circuit for audio has been known (for example, Japanese Patent Application Laid-open No. H09-199955). One type of the operational amplifier circuit for audio includes a plurality of operational amplifier sections to handle a plurality of audio channels. In such a type of operational amplifier circuit, a performance evaluation of crosstalk can be executed by inputting a signal to only one of the operational amplifier sections while keeping the other sections in a non-input state and comparing the outputs of the respective operational amplifiers.

In some cases, the frequency range to be evaluated for crosstalk performance includes not only the vicinity of 1 kHz, but also, for example, 100 Hz or less. The reference voltage supplied to each operational amplifier, as disclosed in Japanese Patent Application Laid-open No. H09-199955, has dependency on frequency due to a first-order low-pass filter constituted by a resistor and a capacitor. Therefore, there may be a case that, although the required crosstalk performance can be met at 1 KHz, there is a risk of failing to meet the required performance at a lower frequency such as 100 Hz.

### SUMMARY

An operational amplifier circuit according to an embodiment includes a reference voltage generation circuit and a plurality of operational amplifier circuit sections. The reference voltage generation circuit is connected to a single power supply. The reference voltage generation circuit is configured to generate a reference voltage signal and output the reference voltage signal. Each of the operational amplifier circuit sections includes an operational amplifier that operates with the single power supply. An output impedance of the reference voltage generation circuit is set to cause a voltage fluctuation amount of the reference voltage signal to be equal to or less than a predetermined value.

### BRIEF DESCRIPTION OF THE DRAWINGS

FIG. 1 is a diagram illustrated to describe an exemplary configuration of an operational amplifier circuit according to a first embodiment;

FIG. 2 is a diagram illustrating an exemplary configuration of a conventional differential input operational amplifier circuit;

FIG. 3 is a diagram illustrated to describe the frequency characteristics of a conventional reference voltage VREF;

FIG. 4 is a diagram illustrated to describe the frequency characteristics of a reference voltage VREF according to the first embodiment;

FIG. 5 is a diagram illustrated to describe an exemplary configuration of an operational amplifier circuit according to a second embodiment;

FIG. 6 is a diagram illustrated to describe the frequency characteristics of a reference voltage VREF according to the second embodiment;

FIG. 7 is a diagram illustrated to describe an exemplary configuration of an operational amplifier circuit according to a third embodiment;

FIG. 8 is a diagram illustrated to describe the frequency characteristics of a reference voltage VREF according to the third embodiment;

FIG. 9 is a diagram illustrated to describe an exemplary configuration of an operational amplifier circuit according to a fourth embodiment;

FIG. 10 is a diagram illustrated to describe the frequency characteristics of a reference voltage VREF of the fourth embodiment;

FIG. 11 is a diagram illustrated to describe an exemplary configuration of an operational amplifier circuit of a fifth embodiment;

FIG. 12 is a diagram illustrated to describe the frequency characteristics of a reference voltage VREF of the fifth embodiment;

FIG. 13 is a diagram illustrated to describe an exemplary configuration of an operational amplifier circuit of a sixth embodiment;

FIG. 14 is a diagram illustrating the configuration of a conventional non-inverting input operational amplifier circuit;

FIG. 15 is a diagram illustrated to describe the results of a simulation of the circuit illustrated in FIG. 14;

FIG. 16 is a diagram illustrated to describe an exemplary configuration of an operational amplifier circuit of a seventh embodiment;

FIG. 17 is a diagram illustrated to describe an exemplary configuration of an operational amplifier circuit of an eighth embodiment;

FIG. 18 is a diagram illustrated to describe an exemplary configuration of an operational amplifier circuit of a ninth embodiment;

FIG. 19 is a diagram illustrated to describe an exemplary configuration of an operational amplifier circuit according to a tenth embodiment;

FIG. 20 is a diagram illustrated to describe an exemplary configuration of an operational amplifier circuit according to an eleventh embodiment;

FIG. 21 is a diagram illustrated to describe the frequency characteristics of reference voltage VREF upon application of a predetermined voltage; and

FIG. 22 is a diagram illustrated to describe an exemplary configuration of an operational amplifier circuit according to a twelfth embodiment.

### DETAILED DESCRIPTION

An operational amplifier circuit according to embodiments of the present disclosure will be described in detail with reference to the accompanying drawings.

### First Embodiment

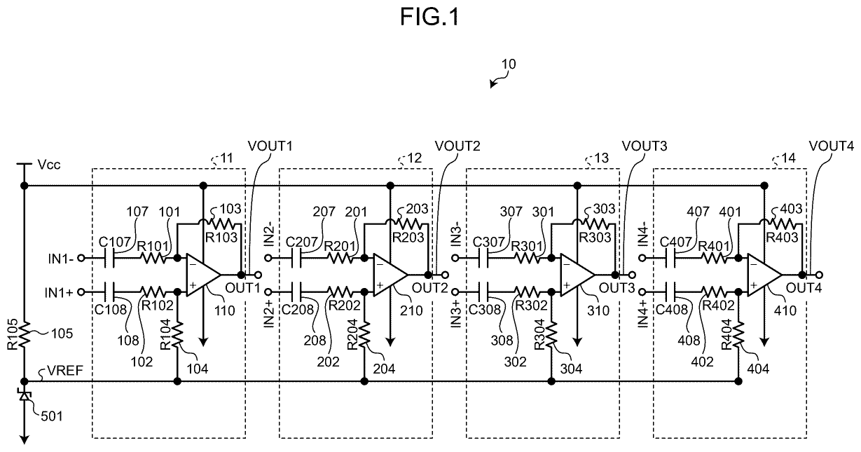

FIG. 1 is a diagram illustrated to describe an exemplary configuration of an operational amplifier circuit according to a first embodiment. The operational amplifier circuit 10 is configured as a differential input amplifier circuit having four inputs and four outputs (4-input/4-output). The operational amplifier circuit 10 includes a first operational amplifier section 11, a second operational amplifier section 12, a third operational amplifier section 13, a fourth operational amplifier section 14, a resistor 105, and a Zener diode 501.

In the configuration described above, the first to fourth operational amplifier sections 11 to 14 constitute a differential input amplifier circuit.

The first operational amplifier section 11 includes a resistor 101, a resistor 102, a feedback resistor 103, a resistor 104, a capacitor 107, a capacitor 108, and a first operational amplifier 110. In the configuration described above, the resistors 101 and 102 function as input resistors, and the capacitors 107 and 108 function as input capacitors.

The resistor 101 has one end connected to an inverting input terminal of the first operational amplifier 110, and has the other end connected to one end of the capacitor 107. The resistor 102 has one end connected to a non-inverting input terminal of the first operational amplifier 110, and has the other end connected to one end of the capacitor 108.

The feedback resistor 103 has one end connected to the output terminal of the first operational amplifier 110, and has the other end connected to one end of the resistor 101. The resistor 104 has one end connected to the non-inverting input terminal of the first operational amplifier 110, and has the other end connected to the connection point between the other end of the resistor 105 and a cathode terminal of the Zener diode 501.

The resistor 105 has one end connected to power supply Vcc, and has the other end connected to the cathode terminal of the Zener diode 501. The capacitor 107 has one end connected to the first inverting input terminal IN1−, and has the other end connected to the other end of the resistor 101.

The capacitor 108 has one end connected to the first non-inverting input terminal IN1+, and has the other end connected to the other end of the resistor 102. The first operational amplifier 110 has one power supply terminal connected to power supply Vcc, and has the other power supply terminal grounded.

The inverting input terminal of the first operational amplifier 110 is connected to one end of the resistor 101, the non-inverting input terminal is connected to one end of the resistor 102, and the output terminal is connected to an output terminal OUT1 of the first operational amplifier section 11.

In the configuration described above, the voltage at a connection point between the resistor 105 and the cathode terminal of the Zener diode 501 is set to a reference voltage VREF.

The second operational amplifier section 12 includes resistors 201 and 202, feedback resistors 203, a resistor 204, capacitors 207 and 208, and a second operational amplifier 210. In the configuration described above, the resistors 201 and 202 function as input resistors, and the capacitors 207 and 208 function as input capacitors.

The resistor 201 has one end connected to an inverting input terminal of the second operational amplifier 210, and has the other end connected to one end of the capacitor 207. The resistor 202 has one end connected to a non-inverting input terminal of the second operational amplifier 210, and has the other end connected to one end of the capacitor 208.

The feedback resistor 203 has one end connected to an output terminal of the second operational amplifier 210, and has the other end connected to one end of the resistor 201. The resistor 204 has one end connected to the non-inverting input terminal of the second operational amplifier 210, and has the other end connected to a connection point between the other end of the resistor 105 and the cathode terminal of the Zener diode 501.

The capacitor 207 has one end connected to a second inverting input terminal IN2−, and has the other end connected to the other end of the resistor 201.

The capacitor 208 has one end connected to a second non-inverting input terminal IN2+, and has the other end connected to the other end of the resistor 202. The second operational amplifier 210 has one power supply terminal connected to the power supply Vcc, and has the other power supply terminal grounded.

The third operational amplifier section 13 includes resistors 301 and 302, feedback resistors 303 and 304, capacitors 307 and 308, and a third operational amplifier 310. In the configuration described above, the resistors 301 and 302 function as input resistors, and the capacitors 307 and 308 function as input capacitors.

The resistor 301 has one end connected to an inverting input terminal of the third operational amplifier 310, and has the other end connected to one end of the capacitor 307. The resistor 302 has one end connected to a non-inverting input terminal of the third operational amplifier 310, and has the other end connected to one end of the capacitor 308.

The feedback resistor 303 has one end connected to an output terminal of the third operational amplifier 310, and has the other end connected to one end of the resistor 301. The resistor 304 has one end connected to a non-inverting input terminal of the third operational amplifier 310, and has the other end connected to the connection point between the other end of the resistor 105 and the cathode terminal of the Zener diode 501.

The capacitor 307 has one end connected to a third inverting input terminal IN3−, and has the other end connected to the other end of the resistor 301.

The capacitor 308 has one end connected to a third non-inverting input terminal IN3+, and has the other end connected to the other end of the resistor 302. The third operational amplifier 310 has a power supply terminal connected to the power supply Vcc, and has the other power supply terminal grounded.

The fourth operational amplifier section 14 includes a resistor 401, a resistor 402, a feedback resistor 403, a resistor 404, a capacitor 407, a capacitor 408, and a fourth operational amplifier 410. In the configuration described above, the resistors 401 and 402 function as input resistors, and the capacitors 407 and 408 function as input capacitors.

The resistor 401 has one end connected to an inverting input terminal of the fourth operational amplifier 410, and has the other end connected to one end of the capacitor 407. The resistor 402 has one end connected to a non-inverting input terminal of the fourth operational amplifier 410, and has the other end connected to one end of the capacitor 408.

The feedback resistor 403 has one end connected to an output terminal of the fourth operational amplifier 410, and has the other end connected to one end of the resistor 401. The resistor 404 has one end connected to the non-inverting input terminal of the fourth operational amplifier 410, and has the other end connected to the connection point between the other end of the resistor 105 and the cathode terminal of the Zener diode 501.

The capacitor 407 has one end connected to a fourth inverting input terminal IN4−, and has the other end connected to the other end of the resistor 401.

The capacitor 408 has one end connected to a fourth non-inverting input terminal IN4+, and has the other end connected to the other end of the resistor 402. The fourth operational amplifier 410 has one power supply terminal connected to the power supply Vcc, and has the other power supply terminal grounded.

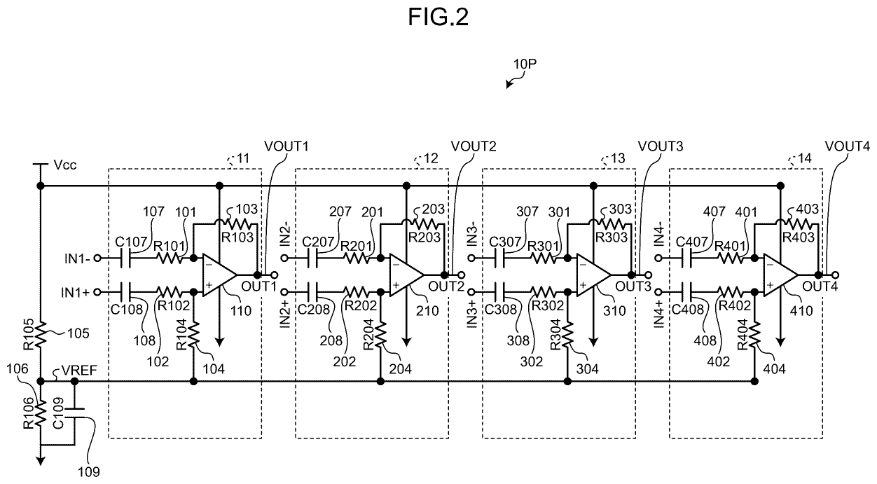

Problems in the conventional art are first described, followed by a detailed description of the embodiment. FIG. 2 is a diagram illustrating an exemplary configuration of a conventional differential input operational amplifier circuit. In FIG. 2, components that are similar to those in FIG. 1 are denoted by the same reference signs.

When a voltage VIN1+ is applied to the first non-inverting input terminal IN1+ of the first operational amplifier section 11 of the conventional differential input operational amplifier circuit 10P, and a voltage VIN1− is applied to the first inverting input terminal IN1− of the first operational amplifier section 11, the output voltage VOUT1 of the output terminal OUT1 of the first operational amplifier 110 is given by Equations (1) and (2) below.

$$( {R}_{105} // {R}_{106} // {C}_{109} ) = \frac{\frac{{R}_{105} {R}_{106}}{{R}_{105} + {R}_{106}} \times \frac{1}{j ω {C}_{109}}}{\frac{{R}_{105} {R}_{106}}{{R}_{105} + {R}_{106}} + \frac{1}{j ω {C}_{109}}} \qquad ( 1 )$$

$${V}_{OUT 1} = - \frac{{R}_{103}}{{R}_{101} + \frac{1}{j ω {C}_{107}}} {V}_{IN 1 -} + \frac{{R}_{101} + {R}_{103} + \frac{1}{j ω {C}_{107}}}{{R}_{101} + \frac{1}{j ω {C}_{107}}} \cdot \frac{{R}_{104} + ( {R}_{105} // {R}_{106} // {C}_{109} )}{\frac{1}{j ω {C}_{108}} + {R}_{102} + {R}_{104} + ( {R}_{105} // {R}_{106} // {C}_{109} )} {V}_{IN 1 +} \qquad ( 2 )$$

Further, when the voltage VIN1+ is applied to the first non-inverting input terminal IN1+, the reference voltage VREF is given by Equation (1) above and Equation (3) below.

$${V}_{REF} = \frac{( {R}_{105} // {R}_{106} // {C}_{109} )}{\frac{1}{j ω {C}_{108}} + {R}_{102} + {R}_{104} + ( {R}_{105} // {R}_{106} // {C}_{109} )} {V}_{IN 1 +} \qquad ( 3 )$$

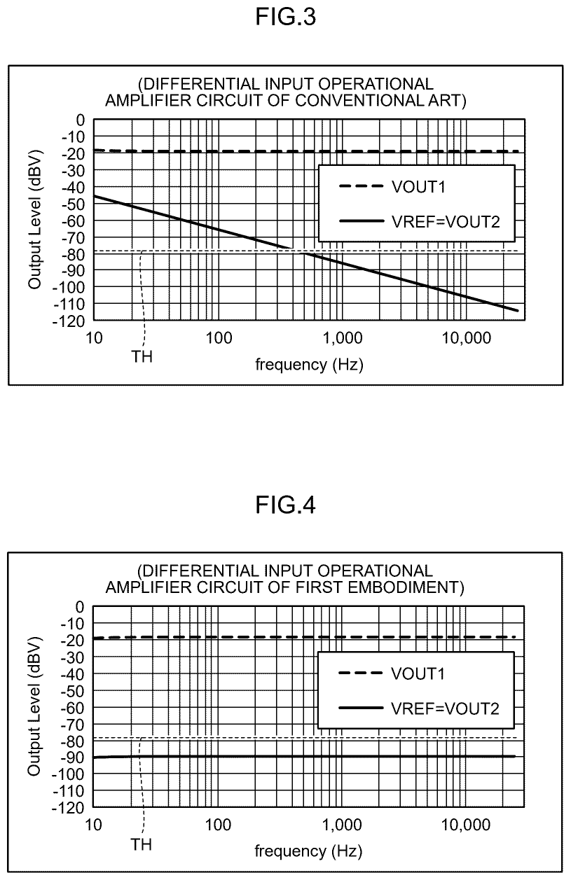

FIG. 3 is a diagram illustrated to describe the frequency characteristics of the reference voltage VREF upon application of a predetermined voltage. FIG. 3 illustrates an example of the frequency characteristics (simulated values) when −18.5 dBV (0=0 deg) is applied to the first non-inverting input terminal IN1+ and −18.5 dBV (0=180 deg) is applied to the first inverting input terminal IN1−. In the illustrated frequency characteristic, θ represents the phase of voltage VIN1+ and voltage VIN1−. The dotted line indicates the output voltage VOUT1 at the output terminal OUT1 of the first operational amplifier 110, and the solid line indicates the voltage of the reference voltage VREF.

In this case, when the second non-inverting input terminal IN2+ and second inverting input terminal IN2− of the second operational amplifier section 12, the third non-inverting input terminal IN3+ and third inverting input terminal IN3− of the third operational amplifier section 13, and the fourth non-inverting input terminal IN4+ and fourth inverting input terminal IN4− of the fourth operational amplifier section 14 are left unconnected (no input), the voltage of the reference voltage VREF becomes equal to the voltages VOUT2, VOUT3, and VOUT4 of the output terminals OUT2, OUT3, and OUT4.

In other words, the above-described phenomenon corresponds to crosstalk from the first non-inverting input terminal IN1+ to the second operational amplifier 210, the third operational amplifier 310, and the fourth operational amplifier 410.

In the example of FIG. 3, the reference voltage VREF exhibits a frequency characteristic with a slope downward at 6 dB/oct, resulting from a first-order low-pass filter that includes resistors 104, 105, and 106 and a capacitor 109.

For this reason, if the required performance for crosstalk is set to 60 dB (as indicated by the dashed line TH in FIG. 3), the requirement is satisfied at 1 KHz; however at frequencies of 500 Hz or lower (particularly at 100 Hz), the requirement is not satisfied, which presents a problem.

FIG. 4 is a diagram illustrated to describe the frequency characteristics of the reference voltage VREF according to the first embodiment. As illustrated in FIG. 1, the reference voltage generation circuit, which is configured using the Zener diode 501 that functions as a constant voltage element, makes it possible to sufficiently reduce the output impedance of the reference voltage generation circuit.

This configuration enables the reference voltage VREF to be maintained at an effectively constant voltage regardless of frequency within the frequency band targeted for performance evaluation of crosstalk. This result enables the required crosstalk performance (60 dB in the above example) to be achieved.

As described above, the first embodiment enables reduction of crosstalk between operational amplifiers in an operational amplifier circuit including plural operational amplifier circuit sections, each having a differential input operational amplifier that operates with a single power supply.

### Second Embodiment

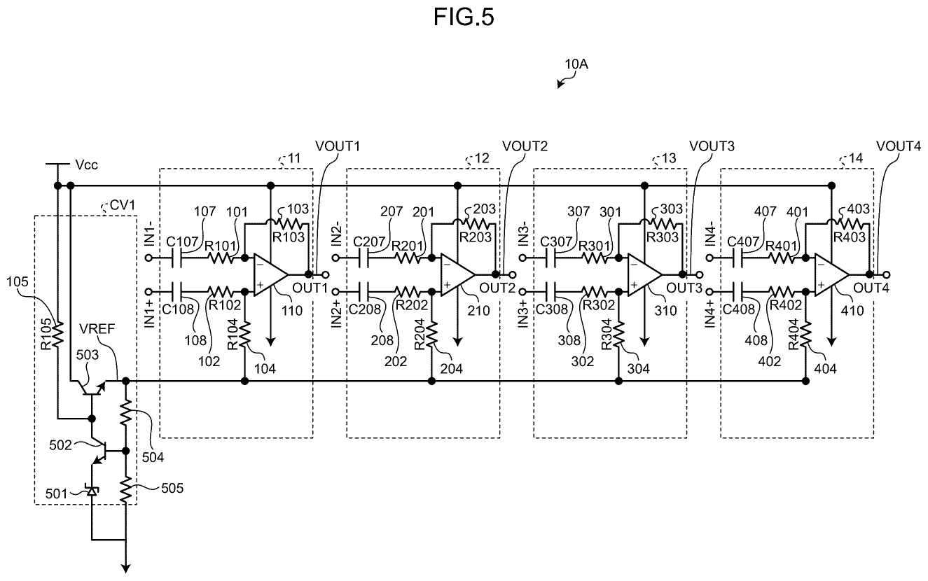

FIG. 5 is a diagram illustrated to describe an exemplary configuration of an operational amplifier circuit according to a second embodiment. In FIG. 5, components similar to those in the first embodiment in FIG. 1 are denoted by the same reference signs. Similar to the above-described operational amplifier circuit 10, an operational amplifier circuit 10A is configured as a 4-input/4-output differential input amplifier circuit. The operational amplifier circuit 10A includes a first operational amplifier section 11, a second operational amplifier section 12, a third operational amplifier section 13, a fourth operational amplifier section 14, and a constant voltage circuit CV1.

In the configuration described above, the constant voltage circuit CV1 functions as a reference voltage generation circuit. Additionally, the first operational amplifier section 11, the second operational amplifier section 12, the third operational amplifier section 13, and the fourth operational amplifier section 14 have configurations similar to those of the first embodiment. Therefore, detailed descriptions thereof are omitted.

The constant voltage circuit CV1 includes a Zener diode 501, a first transistor 502, a second transistor 503, a resistor 105, a resistor 504, and a resistor 505. The anode terminal of the Zener diode 501 is grounded. The emitter terminal of the first transistor 502 is connected to the cathode terminal of the Zener diode 501, and the collector terminal is connected to the other end of the resistor 105.

The collector terminal of the second transistor 503 is connected to a power supply Vcc, the base terminal is connected to the collector terminal of the first transistor 502, and the emitter terminal is connected to resistors 104, 204, 304, 404, and 504, and serves as the output terminal for the reference voltage VREF.

The resistor 504 has one end connected to the emitter terminal of the second transistor 503, and has the other end connected to the base terminal of the first transistor 502. The resistor 505 has one end connected to a connection point between the resistor 504 and the base terminal of the first transistor 502, and has the other end grounded.

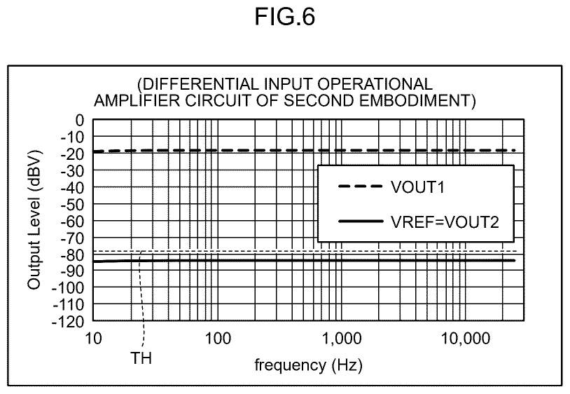

FIG. 6 is a diagram illustrated to describe the frequency characteristics of a reference voltage VREF according to the second embodiment. In the configuration described above, since the majority of the emitter current of the second transistor 503 flows into the resistor 504, the voltage of the reference voltage VREF is not affected by voltage fluctuations at a first non-inverting input terminal IN1+. This configuration enables the constant voltage circuit CV1 functioning as a reference voltage generation circuit to reduce its output impedance to a sufficient degree.

This configuration enables the reference voltage VREF to be maintained at an effectively constant voltage regardless of frequency within the frequency band targeted for performance evaluation of crosstalk. This result enables the required crosstalk performance (60 dB in the above example) to be achieved.

As described above, similar to the first embodiment, the second embodiment enables reduction of crosstalk between the operational amplifiers in an operational amplifier circuit including plural operational amplifier circuit sections, each having a differential input operational amplifier that operates with a single power supply.

### Third Embodiment

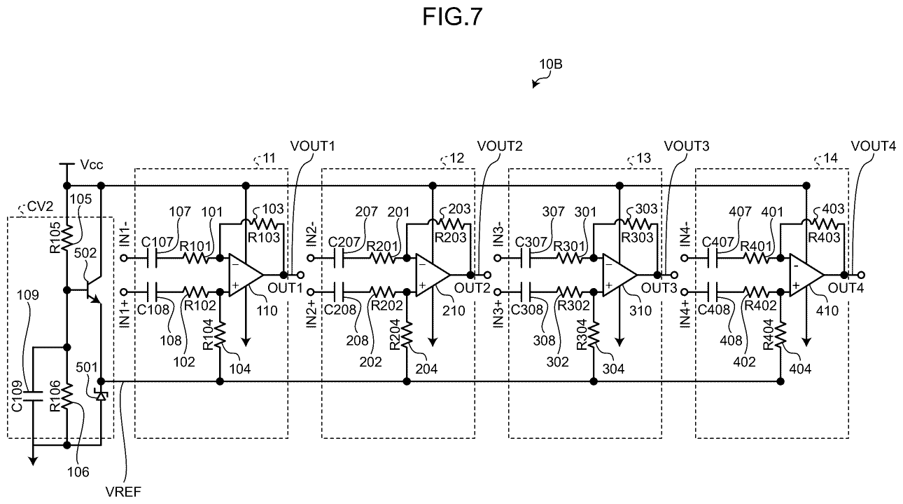

FIG. 7 is a diagram illustrated to describe an exemplary configuration of an operational amplifier circuit of a third embodiment. In FIG. 7, components similar to those of the first embodiment in FIG. 1 and the second embodiment in FIG. 5 are denoted by the same reference signs.

Similar to the above-described operational amplifier circuit 10, an operational amplifier circuit 10B is configured as a 4-input/4-output differential input amplifier circuit. Then, the operational amplifier circuit 10B includes a first operational amplifier section 11, a second operational amplifier section 12, a third operational amplifier section 13, a fourth operational amplifier section 14, and a constant voltage circuit CV2.

In the configuration described above, the constant voltage circuit CV2 functions as a reference voltage generation circuit. Additionally, the first operational amplifier section 11, the second operational amplifier section 12, the third operational amplifier section 13, and the fourth operational amplifier section 14 have configurations similar to those of the first embodiment. Therefore, detailed descriptions thereof are omitted.

The constant voltage circuit CV2 includes a Zener diode 501, a first transistor 502, resistors 105 and 106, and a capacitor 109. The anode terminal of the Zener diode 501 is grounded. The emitter terminal of the first transistor 502 is connected to the cathode terminal of the Zener diode 501, and the collector terminal is connected to the power supply Vcc.

The resistor 105 has one end connected to the power supply Vcc, and has the other end connected to the base terminal of the first transistor 502. The resistor 106 has one end connected to a connection point between the base terminal of the first transistor 502 and the other end of the resistor 105, and has the other end grounded. The capacitor 109 is connected in parallel with the resistor 106.

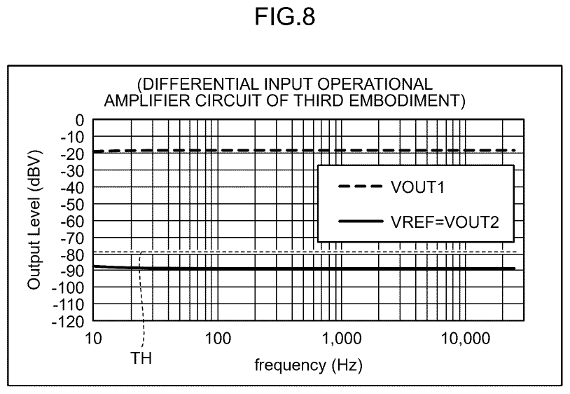

FIG. 8 is a diagram illustrated to describe the frequency characteristics of a reference voltage VREF according to the third embodiment. In the configuration described above, since the majority of the emitter current of the first transistor 502 flows into the Zener diode 501, the voltage of the reference voltage VREF is not affected by voltage fluctuations at the first non-inverting input terminal IN1+. This configuration enables the constant voltage circuit CV2 functioning as a reference voltage generation circuit to reduce its output impedance to a sufficient degree.

This configuration enables the reference voltage VREF to be maintained at an effectively constant voltage regardless of frequency within the frequency band targeted for performance evaluation of crosstalk. This result enables the required crosstalk performance (e.g., 60 dB in the above example) to be achieved, as with the previous embodiments.

As described above, similar to the first and second embodiments, the third embodiment enables reduction of crosstalk between the operational amplifiers in an operational amplifier circuit including plural operational amplifier circuit sections, each having a differential input operational amplifier that operates with a single power supply.

### Fourth Embodiment

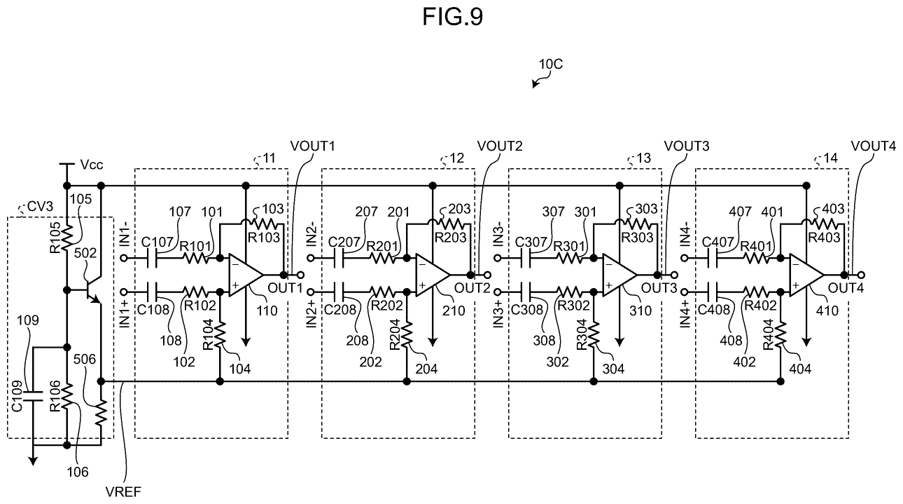

FIG. 9 is a diagram illustrated to describe an exemplary configuration of an operational amplifier circuit according to a fourth embodiment. In FIG. 9, components similar to those of the first embodiment in FIG. 1, the second embodiment in FIG. 5, and the third embodiment in FIG. 7 are denoted by the same reference signs.

Similar to the above-described operational amplifier circuit 10, an operational amplifier circuit 10C is configured as a 4-input/4-output differential input amplifier circuit. Then, the operational amplifier circuit 10C includes a first operational amplifier section 11, a second operational amplifier section 12, a third operational amplifier section 13, a fourth operational amplifier section 14, and a constant voltage circuit CV3.

In the configuration described above, the constant voltage circuit CV3 functions as a reference voltage generation circuit. Additionally, the first operational amplifier section 11, the second operational amplifier section 12, the third operational amplifier section 13, and the fourth operational amplifier section 14 have configurations similar to those of the first embodiment. Therefore, detailed descriptions thereof are omitted.

The constant voltage circuit CV3 includes a first transistor 502, resistors 105 and 106, a capacitor 109, and a resistor 506. The emitter terminal of the first transistor 502 is connected to one end of the resistor 506, and the collector terminal is connected to the power supply Vcc. The resistor 105 has one end connected to the power supply Vcc, and has the other end connected to the base terminal of the first transistor 502.

The resistor 106 has one end connected to a connection point between the base terminal of the first transistor 502 and the other end of the resistor 105, and has the other end grounded. The capacitor 109 is connected in parallel with the resistor 106. The other end of the resistor 506 is grounded.

In the configuration described above, the first transistor 502 and the resistor 506 form an emitter follower.

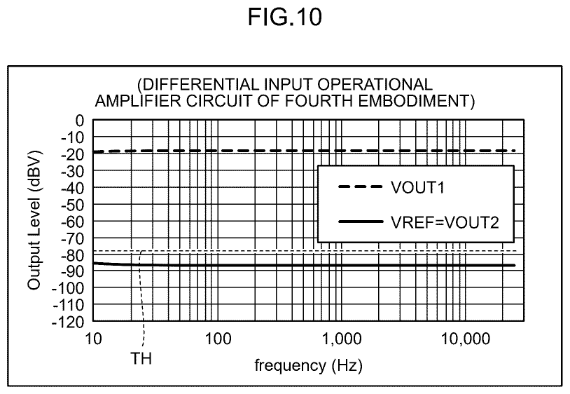

FIG. 10 is a diagram illustrated to describe the frequency characteristics of a reference voltage VREF according to the fourth embodiment. In the configuration described above, since the majority of the emitter current of the first transistor 502 flows into the resistor 506, the voltage of the reference voltage VREF is not affected by voltage fluctuations at the first non-inverting input terminal IN1+.

This configuration enables the reference voltage VREF to be maintained at an effectively constant voltage regardless of frequency within the frequency band targeted for performance evaluation of crosstalk.

This result enables, as illustrated in FIG. 10, the required crosstalk performance (60 dB in the above example) to be achieved, as in the above embodiments.

As described above, similar to the first, second and third embodiments, the fourth embodiment enables reduction of crosstalk between the operational amplifiers in an operational amplifier circuit including plural operational amplifier circuit sections, each having a differential input operational amplifier that operates with a single power supply.

### Fifth Embodiment

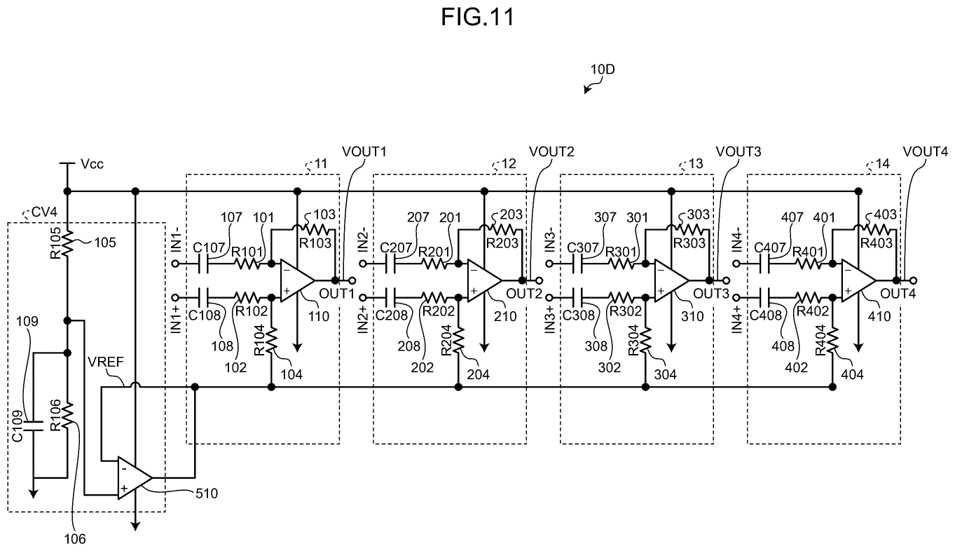

FIG. 11 is a diagram illustrated to describe an exemplary configuration of an operational amplifier circuit according to a fifth embodiment. In FIG. 11, components similar to those in the first embodiment of FIG. 1, the second embodiment of FIG. 5, the third embodiment of FIG. 7 and the fourth embodiment of FIG. 9 are denoted by the same reference signs.

Similar to the above-described operational amplifier circuit 10, an operational amplifier circuit 10D is configured as a 4-input/4-output differential input amplifier circuit. Then, the operational amplifier circuit 10D includes a first operational amplifier section 11, a second operational amplifier section 12, a third operational amplifier section 13, a fourth operational amplifier section 14, and a constant voltage circuit CV4.

In the configuration described above, the constant voltage circuit CV4 functions as a reference voltage generation circuit. Additionally, the first operational amplifier section 11, the second operational amplifier section 12, the third operational amplifier section 13, and the fourth operational amplifier section 14 have configurations similar to those of the first embodiment. Therefore, detailed descriptions thereof are omitted.

The constant voltage circuit CV4 has similar functionality to the constant voltage circuit CV3 of the fourth embodiment. The constant voltage circuit CV4 includes an operational amplifier 510 instead of the emitter follower circuit constituted by the first transistor 502 and the resistor 506. The resistor 105 has one end connected to the power supply Vcc and has the other end connected to one end of the resistor 106.

The resistor 106 has one end connected to the other end of the resistor 105 and has the other end grounded. The operational amplifier 510 has a non-inverting input terminal connected to a connection point between the resistors 105 and 106, and has an output terminal connected to the inverting input terminal. The capacitor 109 is connected in parallel with the resistor 106.

In the configuration described above, the operational amplifier 510 has a low output impedance, similar to the emitter follower in the fourth embodiment.

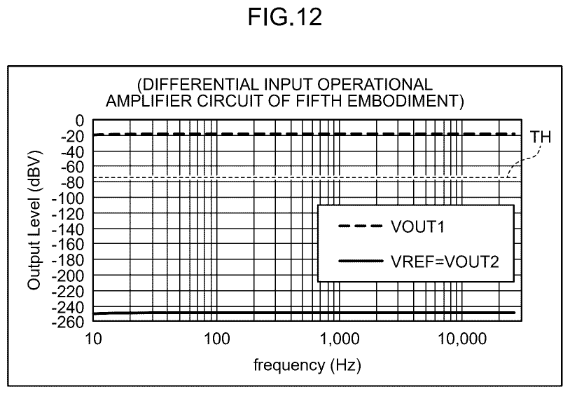

FIG. 12 is a diagram illustrated to describe the frequency characteristics of a reference voltage VREF according to the fifth embodiment. This enables the reference voltage VREF to be maintained at an effectively constant voltage regardless of frequency within the frequency band targeted for performance evaluation of crosstalk. This result enables the required crosstalk performance (60 dB in the above example) to be fully achieved (230 dB in the example of FIG. 12).

As described above, similar to the first, second, third, and fourth embodiments, the fifth embodiment enables reduction of crosstalk between the operational amplifiers in an operational amplifier circuit including plural operational amplifier circuit sections, each having a differential input operational amplifier that operates with a single power supply.

### Sixth Embodiment

In the embodiments described above, the operational amplifier circuit has a differential input configuration. In contrast, a sixth embodiment provides an example of an operational amplifier circuit having a non-inverting input configuration.

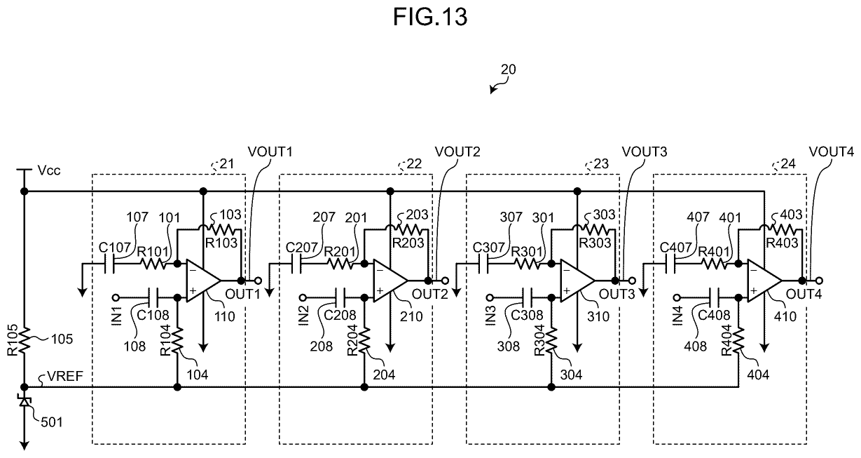

FIG. 13 is a diagram illustrated to describe an exemplary configuration of an operational amplifier circuit of the sixth embodiment. In FIG. 13, components similar to those in the first embodiment of FIG. 1 are denoted by the same reference signs.

The operational amplifier circuit 20 of the sixth embodiment is configured as a 4-input/4-output non-inverting input amplifier circuit. The operational amplifier circuit 20 includes a first operational amplifier section 21, a second operational amplifier section 22, a third operational amplifier section 23, a fourth operational amplifier section 24, a resistor 105, and a Zener diode 501. In the configuration described above, the first operational amplifier section 21 to the fourth operational amplifier section 24 form a non-inverting input amplifier circuit.

The first operational amplifier section 21 includes a resistor 101, a feedback resistor 103, a resistor 104, a capacitor 107, a capacitor 108, and a first operational amplifier 110.

The resistor 101 has one end connected to an inverting input terminal of the first operational amplifier 110, and has the other end connected to one end of the capacitor 107. The feedback resistor 103 has one end connected to the output terminal of the first operational amplifier 110, and has the other end connected to one end of the resistor 101.

The resistor 104 has one end connected to the non-inverting input terminal of the first operational amplifier 110, and has the other end connected to the cathode terminal of the Zener diode 501. The capacitor 107 has one end grounded, and has the other end connected to the other end of the resistor 101.

The capacitor 108 has one end connected to the first non-inverting input terminal IN1, and has the other end connected to the other end of the resistor 104. The first operational amplifier 110 has one power supply terminal connected to power supply Vcc, and has the other power supply terminal grounded.

Further, the first operational amplifier 110 has an inverting input terminal connected to one end of the resistor 101, has a non-inverting input terminal connected to one end of the resistor 104, and has an output terminal connected to the output terminal OUT1 of the first operational amplifier section 21.

In the configuration described above, the voltage at a connection point between the resistor 105 and the cathode terminal of the Zener diode 501 is set to a reference voltage VREF.

The second operational amplifier section 22 includes a resistor 201, a feedback resistor 203, a resistor 204, a capacitor 207, a capacitor 208, and a second operational amplifier 210.

The resistor 201 has one end connected to an inverting input terminal of the second operational amplifier 210, and has the other end connected to one end of the capacitor 207. The feedback resistor 203 has one end connected to an output terminal of the second operational amplifier 210, and has the other end connected to one end of the resistor 201.

The resistor 204 has one end connected to the non-inverting input terminal of the second operational amplifier 210, and has the other end connected to a connection point between the other end of the resistor 105 and the cathode terminal of the Zener diode 501. The capacitor 207 has one end grounded, and has the other end connected to the other end of the resistor 201.

The capacitor 208 has one end connected to the second non-inverting input terminal IN2, and has the other end connected to the other end of the resistor 204. The second operational amplifier 210 has one power supply terminal connected to the power supply Vcc, and has the other power supply terminal grounded.

The third operational amplifier section 23 includes a resistor 301, a feedback resistor 303, a resistor 304, a capacitor 307, a capacitor 308, and a third operational amplifier 310.

The resistor 301 has one end connected to an inverting input terminal of the third operational amplifier 310, and has the other end connected to one end of the capacitor 307. The feedback resistor 303 has one end connected to an output terminal of the third operational amplifier 310, and has the other end connected to one end of the resistor 301.

The resistor 304 has one end connected to a non-inverting input terminal of the third operational amplifier 310, and has the other end connected to the connection point between the other end of the resistor 105 and the cathode terminal of the Zener diode 501. The capacitor 307 has one end grounded, and has the other end connected to the other end of the resistor 301.

The capacitor 308 has one end connected to the third non-inverting input terminal IN3, and has the other end connected to the other end of the resistor 304. The third operational amplifier 310 has a power supply terminal connected to the power supply Vcc, and has the other power supply terminal grounded.

The fourth operational amplifier section 24 includes a resistor 401, a feedback resistor 403, a resistor 404, a capacitor 407, a capacitor 408, and a fourth operational amplifier 410.

The resistor 401 has one end connected to an inverting input terminal of the fourth operational amplifier 410, and has the other end connected to one end of the capacitor 407. The feedback resistor 403 has one end connected to an output terminal of the fourth operational amplifier 410, and has the other end connected to one end of the resistor 401.

The resistor 404 has one end connected to the non-inverting input terminal of the fourth operational amplifier 410, and has the other end connected to the connection point between the other end of the resistor 105 and the cathode terminal of the Zener diode 501. The capacitor 407 has one end grounded, and has the other end connected to the other end of the resistor 401.

The capacitor 408 has one end connected to the fourth non-inverting input terminal IN4, and has the other end connected to the other end of the resistor 404. The fourth operational amplifier 410 has one power supply terminal connected to the power supply Vcc, and has the other power supply terminal grounded.

Prior to the detailed description of the sixth embodiment, the problems in the conventional operational amplifier having a non-inverting input configuration will be described.

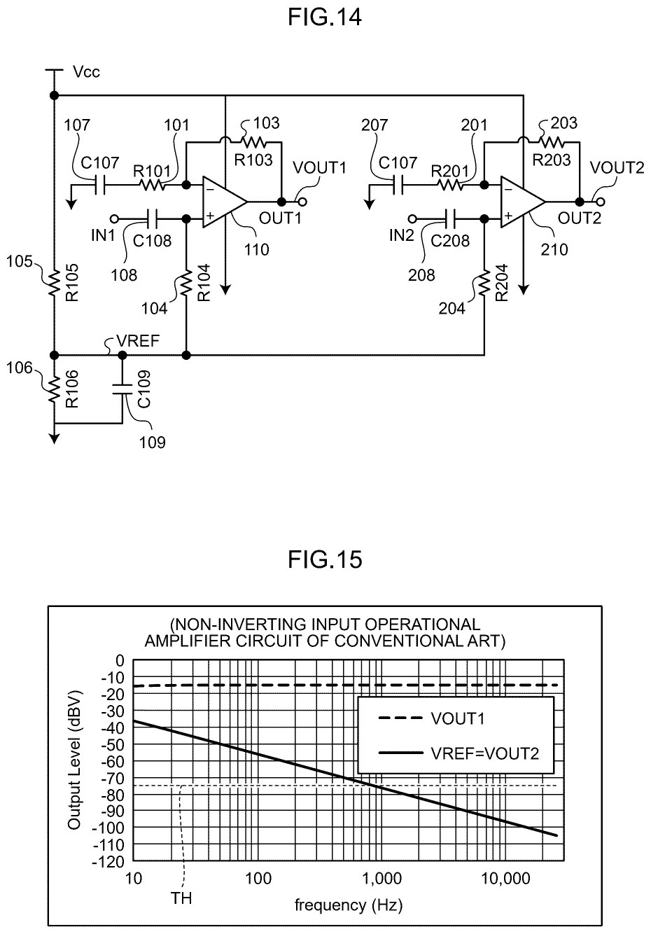

FIG. 14 is a diagram illustrating the configuration of a conventional operational amplifier circuit with a non-inverting input. FIG. 14 illustrates the configuration of the operational amplifier circuit disclosed in Japanese Patent Application Laid-open No. H09-199955. The first output voltage VOUT1, which is the voltage at the first output terminal OUT1 when an input voltage VIN1 is applied to the input terminal IN1, is given by Equations (4) and (5) below.

$${V}_{OUT 1} = \frac{{R}_{103} + {R}_{101} + \frac{1}{j ω {C}_{107}}}{{R}_{101} + \frac{1}{j ω {C}_{107}}} \cdot \frac{{R}_{104} + ( {R}_{105} // {R}_{106} // {C}_{109} )}{\frac{1}{j ω {C}_{108}} + {R}_{104} + ( {R}_{105} // {R}_{106} // {C}_{109} )} {V}_{IN 1} \qquad ( 4 )$$

$$( {R}_{105} // {R}_{106} // {C}_{109} ) = \frac{\frac{{R}_{105} {R}_{106}}{{R}_{105} + {R}_{106}} \times \frac{1}{j ω {C}_{109}}}{\frac{{R}_{105} {R}_{106}}{{R}_{105} + {R}_{106}} + \frac{1}{j ω {C}_{109}}} \qquad ( 5 )$$

The reference voltage VREF when the voltage VIN1 is applied to the non-inverting input terminal IN1 is given by Equation (5) above and Equation (6) below.

$${V}_{REF} = \frac{( {R}_{105} // {R}_{106} // {C}_{109} )}{\frac{1}{j ω {C}_{108}} + {R}_{104} + ( {R}_{105} // {R}_{106} // {C}_{109} )} {V}_{IN 1} \qquad ( 6 )$$

FIG. 15 is a diagram illustrated to describe the simulation results of the circuit in FIG. 14. FIG. 15 illustrates an example of the characteristics (simulation values) when VIN1=−18.5 dBV is input.

In FIG. 15, the dotted line indicates the output VOUT1 of the first output terminal OUT1, and the solid line indicates the reference voltage VREF. In this regard, if no input is applied to the non-inverting input terminal IN2, the voltage of the reference voltage VREF becomes equal to the voltage VOUT2 at the second output terminal OUT2, which results in crosstalk from the non-inverting input terminal IN1 of the first operational amplifier 110 to the second operational amplifier 210.

By the way, as one method of evaluating crosstalk performance, a rated input is applied to the non-inverting input terminal IN1 of the first operational amplifier 110, while no input is applied to the non-inverting input terminal IN2 of the second operational amplifier 210, and the output difference between the output terminal OUT1 of the first operational amplifier 110 and the output terminal OUT2 of the second operational amplifier 210 is observed. In some cases, crosstalk is required to be evaluated not only in the vicinity of 1 kHz, but also at frequencies below 100 Hz.

As illustrated in FIG. 15, the reference voltage VREF has frequency dependency. A first-order low-pass filter constituted by resistors 104, 105, and 106, and the capacitor 109 exhibits a characteristic of a 6 dB/octave downward slope. Therefore, if the required performance for crosstalk is set to 60 dB, a problem may arise such that the requirement is not satisfied at 100 Hz although satisfied at 1 KHz.

In the sixth embodiment, as in the foregoing first embodiment, the reference voltage generation circuit is constituted by using the Zener diode 501 functioning as a constant voltage element.

This sufficiently reduces the output impedance of the reference voltage generation circuit, allowing the reference voltage VREF to be maintained at a constant voltage regardless of frequency in the frequency band targeted for performance evaluation of crosstalk. This result enables the required crosstalk performance (e.g., 60 dB) to be achieved.

According to the sixth embodiment, it is possible to reduce crosstalk between the operational amplifiers in an operational amplifier circuit having plural operational amplifier circuit sections, each having a non-inverting input operational amplifier that operates with a single power supply.

### Seventh Embodiment

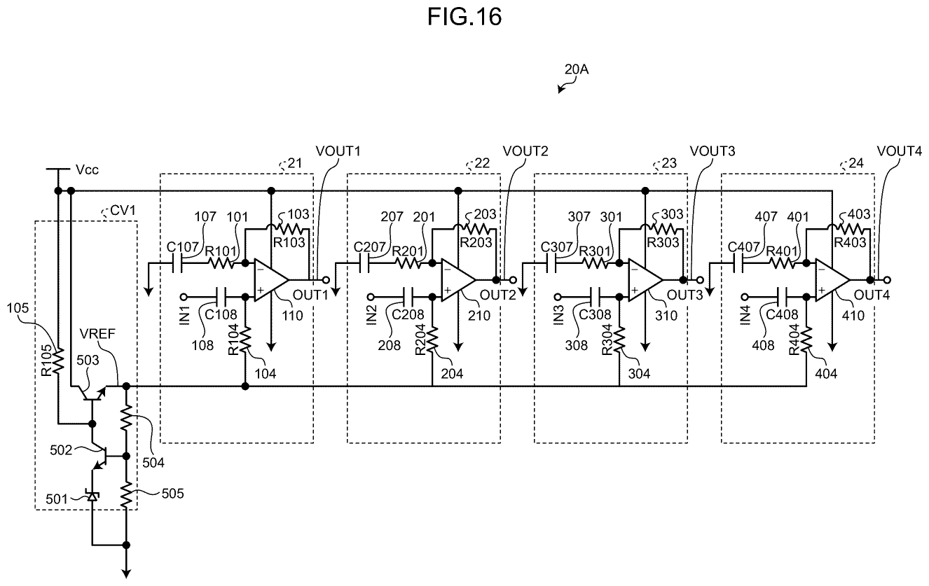

FIG. 16 is a diagram illustrated to describe an exemplary configuration of an operational amplifier circuit according to a seventh embodiment. In FIG. 16, components similar to those in the sixth embodiment of FIG. 13 are denoted by the same reference signs.

Similar to the above-described operational amplifier circuit 20, an operational amplifier circuit 20A is configured as a 4-input/4-output non-inverting input amplifier circuit. Then, the operational amplifier circuit 20A includes a first operational amplifier section 21, a second operational amplifier section 22, a third operational amplifier section 23, a fourth operational amplifier section 24, and a constant voltage circuit CV1. In the configuration described above, the constant voltage circuit CV1 functions as a reference voltage generation circuit.

The first operational amplifier section 21, the second operational amplifier section 22, the third operational amplifier section 23, and the fourth operational amplifier section 24 have configurations similar to those in the sixth embodiment. Therefore, detailed descriptions thereof are omitted.

The constant voltage circuit CV1 includes a Zener diode 501, a first transistor 502, a second transistor 503, a resistor 105, a resistor 504, and a resistor 505.

The anode terminal of the Zener diode 501 is grounded. The emitter terminal of the first transistor 502 is connected to the cathode terminal of the Zener diode 501, and the collector terminal is connected to the other end of the resistor 105.

In the second transistor 503, the collector terminal is connected to the power supply Vcc, the base terminal is connected to the collector terminal of the first transistor 502, and the emitter terminal is connected to the resistors 104, 204, 304, 404, and 504. The emitter terminal of the second transistor 503 functions as the output terminal for the reference voltage VREF.

The resistor 504 has one end connected to the emitter terminal of the second transistor 503, and has the other end connected to the base terminal of the first transistor 502. The resistor 505 has one end connected to a connection point between the resistor 504 and the base terminal of the first transistor 502, and has the other end grounded.

In the configuration described above, since the majority of the emitter current of the second transistor 503 flows into the resistor 504, the voltage of the reference voltage VREF is not affected by the voltage fluctuations at the first non-inverting input terminal IN1. This configuration enables the constant voltage circuit CV1 functioning as a reference voltage generation circuit to reduce its output impedance to a sufficient degree.

This configuration enables the reference voltage VREF to be maintained at an effectively constant voltage regardless of frequency within the frequency band targeted for performance evaluation of crosstalk. This result enables the required crosstalk performance (60 dB in the above example) to be achieved.

As described above, the seventh embodiment enables reduction of crosstalk between the operational amplifiers in an operational amplifier circuit having plural operational amplifier circuit sections each having a non-inverting input operational amplifier that operates with a single power supply, as in the sixth embodiment.

### Eighth Embodiment

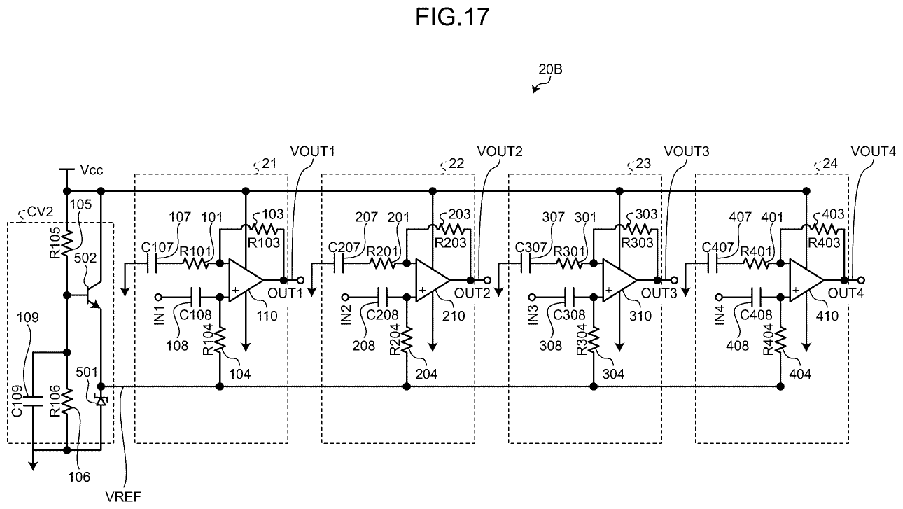

FIG. 17 is a diagram illustrated to describe an exemplary configuration of an operational amplifier circuit of an eighth embodiment. In FIG. 17, components similar to those in the sixth embodiment of FIG. 13 and the seventh embodiment of FIG. 16 are denoted by the same reference signs.

Similar to the above-described operational amplifier circuit 20, an operational amplifier circuit 20B is configured as a four-input/four-output non-inverting input amplifier circuit. Then, the operational amplifier circuit 20B includes a first operational amplifier section 21, a second operational amplifier section 22, a third operational amplifier section 23, a fourth operational amplifier section 24, and a constant voltage circuit CV2. In the configuration described above, the constant voltage circuit CV2 functions as a reference voltage generation circuit.

The first operational amplifier section 21, the second operational amplifier section 22, the third operational amplifier section 23, and the fourth operational amplifier section 24 have configurations similar to those of the sixth embodiment. Therefore, detailed descriptions thereof are omitted.

The constant voltage circuit CV2 includes a Zener diode 501, a first transistor 502, resistors 105 and 106, and a capacitor 109. The anode terminal of the Zener diode 501 is grounded. In the first transistor 502, the emitter terminal is connected to the cathode terminal of the Zener diode 501, and the collector terminal is connected to the power supply Vcc.

The resistor 105 has one end connected to the power supply Vcc, and has the other end connected to the base terminal of the first transistor 502. The resistor 106 has one end connected to a connection point between the base terminal of the first transistor 502 and the other end of the resistor 105, and has the other end grounded. The capacitor 109 is connected in parallel with the resistor 106.

In the configuration described above, the majority of the emitter current of the first transistor 502 flows into the Zener diode 501. Therefore, the voltage of the reference voltage VREF is not affected by voltage fluctuations at the first non-inverting input terminal IN1. This configuration enables the constant voltage circuit CV2 functioning as a reference voltage generation circuit to reduce its output impedance to a sufficient degree.

This configuration enables the reference voltage VREF to be maintained at an effectively constant voltage regardless of frequency within the frequency band targeted for performance evaluation of crosstalk. This result enables the required crosstalk performance (e.g., 60 dB in the above example) to be achieved, as with the previous embodiments.

As described above, the eighth embodiment enables reduction of crosstalk between the operational amplifiers in an operational amplifier circuit having plural operational amplifier circuit sections each having a non-inverting input operational amplifier operating with a single power supply, similar to the sixth and seventh embodiments.

### Ninth Embodiment

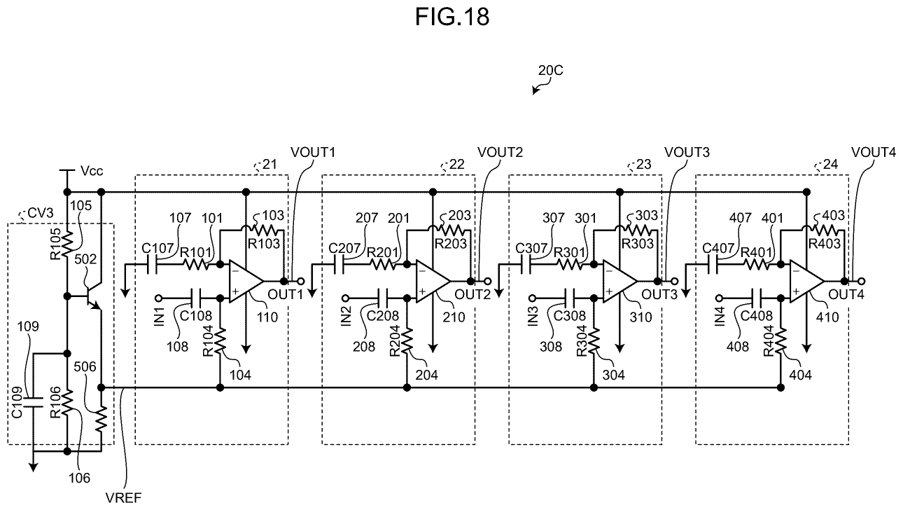

FIG. 18 is a diagram illustrated to describe an exemplary configuration of an operational amplifier circuit of a ninth embodiment. In FIG. 18, components similar to those of the sixth embodiment of FIG. 13, the seventh embodiment of FIG. 16, and the eighth embodiment of FIG. 17 are denoted by the same reference signs.

Similar to the above-described operational amplifier circuit 20, an operational amplifier circuit 20C is configured as a 4-input/4-output non-inverting input amplifier circuit. Then, the operational amplifier circuit 20C includes a first operational amplifier section 21, a second operational amplifier section 22, a third operational amplifier section 23, a fourth operational amplifier section 24, and a constant voltage circuit CV3. In the configuration described above, the constant voltage circuit CV3 functions as a reference voltage generation circuit.

The first operational amplifier section 21, the second operational amplifier section 22, the third operational amplifier section 23, and the fourth operational amplifier section 24 have configurations similar to those of the sixth embodiment. Therefore, detailed descriptions thereof are omitted.

The constant voltage circuit CV3 includes a first transistor 502, resistors 105 and 106, a capacitor 109, and a resistor 506. In the first transistor 502, the emitter terminal is connected to one end of the resistor 506, and the collector terminal is connected to the power supply Vcc. The resistor 105 has one end connected to the power supply Vcc, and has the other end connected to the base terminal of the first transistor 502.

The resistor 106 has one end connected to a connection point between the base terminal of the first transistor 502 and the other end of the resistor 105, and has the other end grounded. The capacitor 109 is connected in parallel with the resistor 106. The other end of the resistor 506 is grounded.

In the configuration described above, the first transistor 502 and the resistor 506 form an emitter follower.

The majority of the emitter current of the first transistor 502 flows into the resistor 506. Therefore, the voltage of the reference voltage VREF is not affected by voltage fluctuations at the first non-inverting input terminal IN1.

This configuration enables the reference voltage VREF to be maintained at an effectively constant voltage regardless of frequency within the frequency band targeted for performance evaluation of crosstalk.

This result enables the required crosstalk performance (e.g., 60 dB) to be achieved over a wide frequency range, as in the above embodiments.

As described above, the ninth embodiment enables reduction of crosstalk between the operational amplifiers in an operational amplifier circuit having plural operational amplifier circuit sections each having a non-inverting input operational amplifier that operates with a single power supply, similar to the sixth, seventh, and eighth embodiments.

### Tenth Embodiment

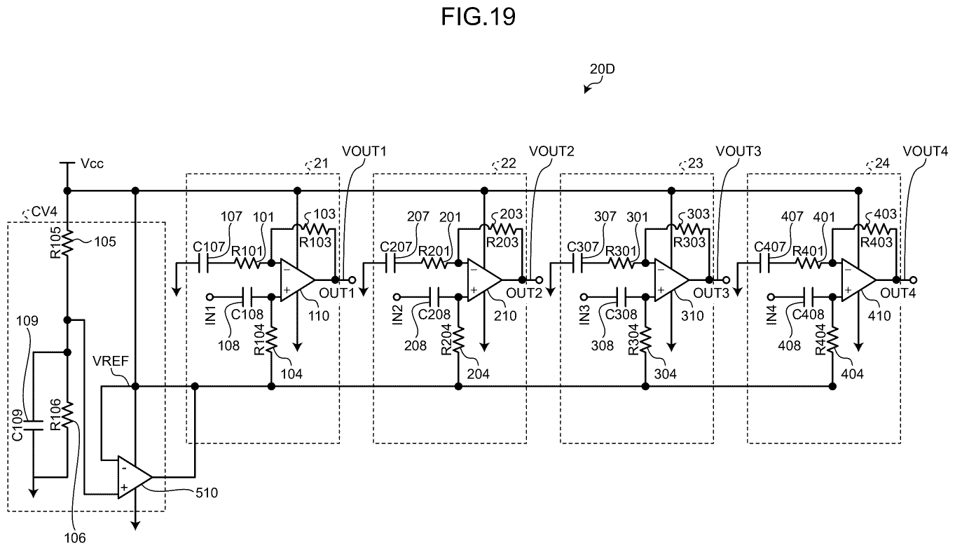

FIG. 19 is a diagram illustrated to describe an exemplary configuration of an operational amplifier circuit according to a tenth embodiment. In FIG. 19, components similar to those of the sixth embodiment of FIG. 13, the seventh embodiment of FIG. 16, the eighth embodiment of FIG. 17, and the ninth embodiment of FIG. 18 are denoted by the same reference signs.

Similar to the above-described operational amplifier circuit 20, an operational amplifier circuit 20D is configured as a 4-input/4-output non-inverting input amplifier circuit. Then, the operational amplifier circuit 20D includes a first operational amplifier section 21, a second operational amplifier section 22, a third operational amplifier section 23, a fourth operational amplifier section 24, and a constant voltage circuit CV4.

In the configuration described above, the constant voltage circuit CV4 functions as a reference voltage generation circuit. The first operational amplifier section 21, the second operational amplifier section 22, the third operational amplifier section 23, and the fourth operational amplifier section 24 have configurations similar to those of the sixth embodiment. Therefore, detailed descriptions thereof are omitted.

The constant voltage circuit CV4 has functionality similar to the constant voltage circuit CV3 in the ninth embodiment. The constant voltage circuit CV4 includes an operational amplifier 510 instead of the emitter follower circuit constituted by the first transistor 502 and the resistor 506. The resistor 105 has one end connected to the power supply Vcc and has the other end connected to one end of the resistor 106.

The resistor 106 has one end connected to the other end of the resistor 105 and has the other end grounded. The operational amplifier 510 has a non-inverting input terminal connected to a connection point between the resistors 105 and 106, and has an output terminal connected to the inverting input terminal. The capacitor 109 is connected in parallel with the resistor 106.

In the configuration described above, the operational amplifier 510 has a low output impedance, similar to the emitter follower in the ninth embodiment.

This enables the reference voltage VREF to be maintained at an effectively constant voltage regardless of frequency within the frequency band targeted for performance evaluation of crosstalk. This result enables the required crosstalk performance to be fully achieved, as in the above embodiments. As described above, the tenth embodiment enables reduction of crosstalk between the operational amplifiers in an operational amplifier circuit including plural operational amplifier circuit sections, each having a non-inverting input operational amplifier that operates with a single power supply, similar to the sixth, seventh, eighth and ninth embodiments.

### Eleventh Embodiment

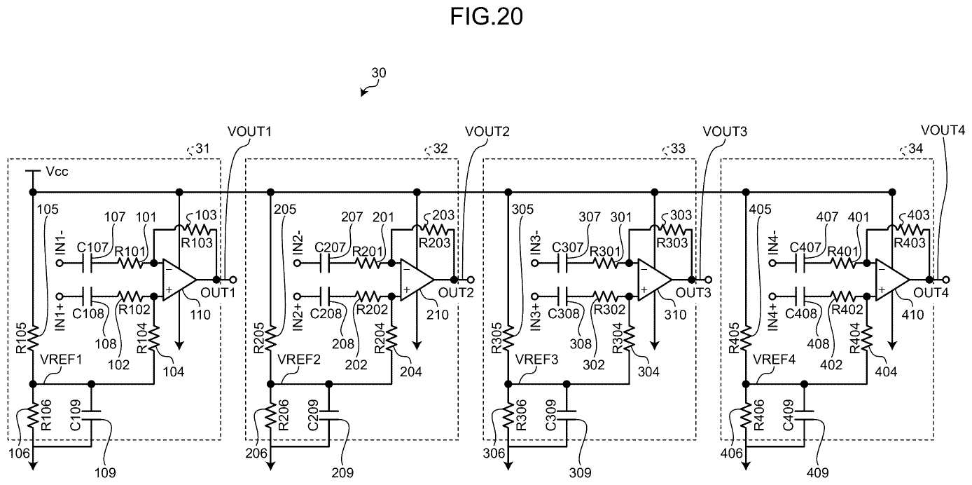

FIG. 20 is a diagram illustrated to describe an exemplary configuration of an operational amplifier circuit of an eleventh embodiment. An operational amplifier circuit 30 is configured as a 4-input/4-output differential input amplifier circuit. The operational amplifier circuit 30 includes a first operational amplifier section 31, a second operational amplifier section 32, a third operational amplifier section 33, and a fourth operational amplifier section 34.

In the configuration described above, the first operational amplifier section 31 to the fourth operational amplifier section 34 form a differential input amplifier circuit.

The first operational amplifier section 31 includes a resistor 101, a resistor 102, a feedback resistor 103, a resistor 104, a resistor 105, a resistor 106, a capacitor 107, a capacitor 108, a capacitor 109, and a first operational amplifier 110. In the configuration described above, the resistors 101 and 102 function as input resistors, and the capacitors 107 and 108 function as input capacitors. The resistor 101 has one end connected to an inverting input terminal of the first operational amplifier 110, and has the other end connected to one end of the capacitor 107.

The resistor 102 has one end connected to a non-inverting input terminal of the first operational amplifier 110, and has the other end connected to one end of the capacitor 108. The feedback resistor 103 has one end connected to the output terminal of the first operational amplifier 110, and has the other end connected to one end of the resistor 101.

The resistor 104 has one end connected to the non-inverting input terminal of the first operational amplifier 110. The resistor 105 has one end connected to the power supply Vcc, and has the other end connected to the other end of the resistor 104. The resistor 106 has one end connected to the connection point between the resistors 104 and 105, and has the other end grounded.

The capacitor 107 has one end connected to the first inverting input terminal IN1−, and has the other end connected to the other end of the resistor 101. The capacitor 108 has one end connected to the first non-inverting input terminal IN1+, and has the other end connected to the other end of the resistor 102.

The capacitor 109 is connected in parallel with the resistor 106. The first operational amplifier 110 has one power supply terminal connected to power supply Vcc, and has the other power supply terminal grounded.

In the configuration described above, the resistors 105 and 106 function as a voltage dividing resistor, dividing the voltage of the power supply Vcc and outputting the divided voltage as a reference voltage VREF1 via the resistor 104 to the non-inverting input terminal of the first operational amplifier 110.

The resistors 104, 105, and 106 and the capacitor 109 function as a first-order low-pass filter, preventing high-frequency noise of the reference voltage VREF1 from being input to the first operational amplifier 110.

The second operational amplifier section 32 includes a resistor 201, a resistor 202, a feedback resistor 203, a resistor 204, a resistor 205, a resistor 206, a capacitor 207, a capacitor 208, a capacitor 209, and a second operational amplifier 210. In the configuration described above, the resistors 201 and 202 function as input resistors, and the capacitors 207 and 208 function as input capacitors. The resistor 201 has one end connected to an inverting input terminal of the second operational amplifier 210, and has the other end connected to one end of the capacitor 207.

The resistor 202 has one end connected to a non-inverting input terminal of the second operational amplifier 210, and has the other end connected to one end of the capacitor 208. The feedback resistor 203 has one end connected to an output terminal of the second operational amplifier 210, and has the other end connected to one end of the resistor 201.

The resistor 204 has one end connected to the non-inverting input terminal of the second operational amplifier 210. The resistor 205 has one end connected to the power supply Vcc, and has the other end connected to the other end of the resistor 204. The resistor 206 has one end connected to the connection point between the resistors 204 and 205, and has the other end grounded.

The capacitor 207 has one end connected to a second inverting input terminal IN2−, and has the other end connected to the other end of the resistor 201. The capacitor 208 has one end connected to a second non-inverting input terminal IN2+, and has the other end connected to the other end of the resistor 202.

The capacitor 209 is connected in parallel with the resistor 206. The second operational amplifier 210 has one power supply terminal connected to the power supply Vcc, and has the other power supply terminal grounded.

In the configuration described above, the resistors 205 and 206 function as a voltage dividing resistor, dividing the voltage of the power supply Vcc and outputting the divided voltage as a reference voltage VREF2 via the resistor 204 to the non-inverting input terminal of the second operational amplifier 210.

Moreover, the resistors 204, 205, and 206 and the capacitor 209 function as a first-order low-pass filter, preventing high-frequency noise of the reference voltage VREF2 from being input to the second operational amplifier 210.

The third operational amplifier section 33 includes resistors 301 and 302, a feedback resistor 303, resistors 304, 305, and 306, capacitors 307, 308, and 309, and a third operational amplifier 310. In the configuration described above, the resistors 301 and 302 function as input resistors, and the capacitors 307 and 308 function as input capacitors. The resistor 301 has one end connected to an inverting input terminal of the third operational amplifier 310, and has the other end connected to one end of the capacitor 307.

The resistor 302 has one end connected to a non-inverting input terminal of the third operational amplifier 310, and has the other end connected to one end of the capacitor 308. The feedback resistor 303 has one end connected to an output terminal of the third operational amplifier 310, and has the other end connected to one end of the resistor 301.

The resistor 304 has one end connected to the non-inverting input terminal of the third operational amplifier 310. The resistor 305 has one end connected to the power supply Vcc, and has the other end connected to the other end of the resistor 304. The resistor 306 has one end connected to the connection point between the resistors 304 and 305, and has the other end grounded.

The capacitor 307 has one end connected to a third inverting input terminal IN3−, and has the other end connected to the other end of the resistor 301. The capacitor 308 has one end connected to a third non-inverting input terminal IN3+, and has the other end connected to the other end of the resistor 302.

The capacitor 309 is connected in parallel with the resistor 306. The third operational amplifier 310 has a power supply terminal connected to the power supply Vcc, and has the other power supply terminal grounded.

In the configuration described above, the resistors 305 and 306 function as a voltage dividing resistor, dividing the voltage of the power supply Vcc and outputting the divided voltage as a reference voltage VREF3 via the resistor 304 to the non-inverting input terminal of the third operational amplifier 310.

Moreover, the resistors 304, 305, and 306 and the capacitor 309 function as a first-order low-pass filter, preventing high-frequency noise of the reference voltage VREF3 from being input to the third operational amplifier 310.

The fourth operational amplifier section 34 includes resistors 401 and 402, a feedback resistor 403, resistors 404, 405, and 406, capacitors 407, 408, and 409, and a fourth operational amplifier 410. In the configuration described above, the resistors 401 and 402 function as input resistors, and the capacitors 407 and 408 function as input capacitors. The resistor 401 has one end connected to an inverting input terminal of the fourth operational amplifier 410, and has the other end connected to one end of the capacitor 407.

The resistor 402 has one end connected to a non-inverting input terminal of the fourth operational amplifier 410, and has the other end connected to one end of the capacitor 408. The feedback resistor 403 has one end connected to an output terminal of the fourth operational amplifier 410, and has the other end connected to one end of the resistor 401.

The resistor 404 has one end connected to the non-inverting input terminal of the fourth operational amplifier 410. The resistor 405 has one end connected to the power supply Vcc, and has the other end connected to the other end of the resistor 404. The resistor 406 has one end connected to the connection point between the resistors 404 and 405, and has the other end grounded.

The capacitor 407 has one end connected to a fourth inverting input terminal IN4−, and has the other end connected to the other end of the resistor 401. The capacitor 408 has one end connected to a fourth non-inverting input terminal IN4+, and has the other end connected to the other end of the resistor 402.

The capacitor 409 is connected in parallel with the resistor 406. The fourth operational amplifier 410 has one power supply terminal connected to the power supply Vcc, and has the other power supply terminal grounded.

In the configuration described above, the resistors 405 and 406 function as voltage dividing resistors, dividing the voltage of the power supply Vcc and outputting the divided voltage as a reference voltage VREF4 via the resistor 404 to the non-inverting input terminal of the fourth operational amplifier 410.

Moreover, the resistors 404, 405, and 406 and the capacitor 409 function as a first-order low-pass filter, preventing high-frequency noise of the reference voltage VREF4 from being input to the fourth operational amplifier 410.

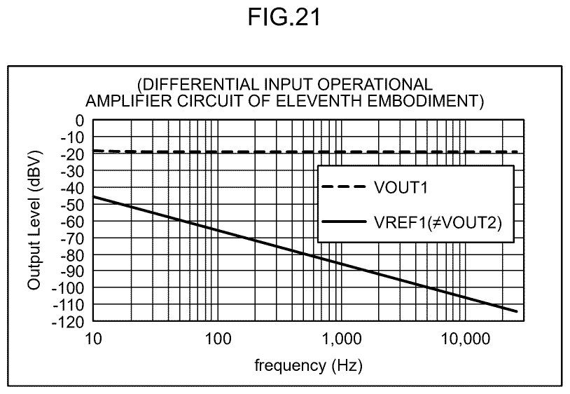

FIG. 21 is a diagram illustrated to describe the frequency characteristics of a reference voltage VREF1 upon application of a predetermined voltage. FIG. 21 illustrates an example (simulated value) of frequency characteristics when −18.5 dBV (θ=0 deg) is applied to the first non-inverting input terminal IN1+ and −18.5 dBV (θ=180 deg) is applied to the first inverting input terminal IN1−. In the illustrated frequency characteristic, θ represents the phase of voltage VIN1+ and voltage VIN1−.

The dotted line indicates the output voltage VOUT1 of the output terminal OUT1 of the first operational amplifier 110, and the solid line indicates the voltage of the reference voltage VREF1. In the configuration described above, the reference voltage VREF1 and the reference voltages VREF2 to VREF4 are mutually uncorrelated, and the reference voltages VREF2 to VREF4 are not affected by the reference voltage VREF1.

Therefore, even if −18.5 dBV (0=0 deg) is input to the first non-inverting input terminal IN1+ of the first operational amplifier 110, the input signal to the first non-inverting input terminal IN1+ is not output to the reference voltages VREF2 to VREF4. The output levels of the reference voltages VREF2 to VREF4 due to the input at the first non-inverting input terminal IN1+ remain at −∞.

For similar reasons, it can be understood that no crosstalk occurs among the differential input of the first operational amplifier 110, the second operational amplifier 210, the third operational amplifier 310, and the fourth operational amplifier 410. As described above, according to the eleventh embodiment, the channels respectively corresponding to the first operational amplifier 110, the second operational amplifier 210, the third operational amplifier 310, and the fourth operational amplifier 410 (e.g., audio channels) are separated from one another, and the corresponding reference voltages VREF1 to VREF4 are mutually uncorrelated. Therefore, crosstalk does not occur.

### Twelfth Embodiment

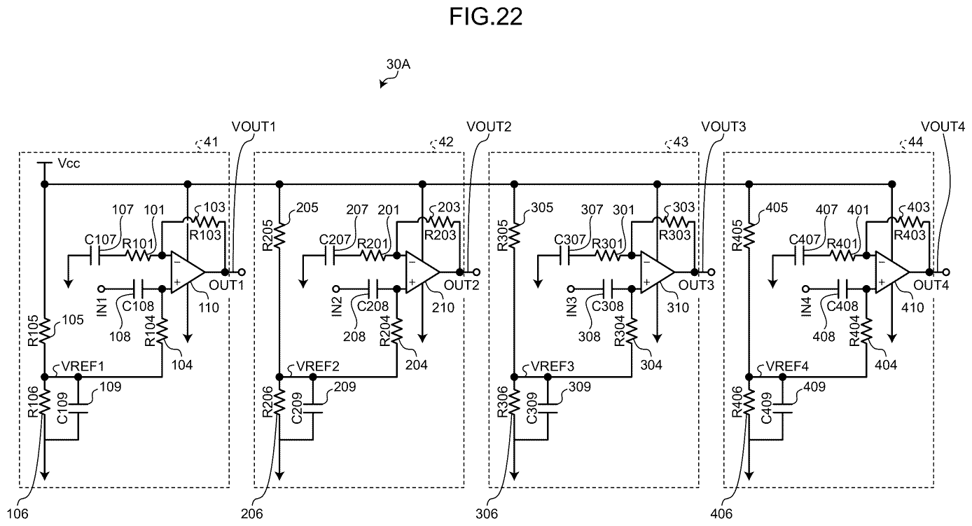

In the eleventh embodiment described above, a differential input operational amplifier circuit is described, but the present twelfth embodiment is an embodiment of a non-inverting input operational amplifier circuit. FIG. 22 is a diagram illustrated to describe an exemplary configuration of an operational amplifier circuit of the twelfth embodiment. In FIG. 22, components similar to those in the sixth embodiment of FIG. 13 are denoted by the same reference signs.

An operational amplifier circuit 30A of the twelfth embodiment is configured as a 4-input/4-output non-inverting input amplifier circuit. The operational amplifier circuit 30A includes a first operational amplifier section 41, a second operational amplifier section 42, a third operational amplifier section 43, and a fourth operational amplifier section 44. In the configuration described above, the first operational amplifier section 41 to the fourth operational amplifier section 44 form a non-inverting input amplifier circuit.

The first operational amplifier section 41 includes a resistor 101, a feedback resistor 103, a resistor 104, a resistor 105, a resistor 106, a capacitor 107, a capacitor 108, a capacitor 109, and a first operational amplifier 110. The resistor 101 has one end connected to an inverting input terminal of the first operational amplifier 110, and has the other end connected to one end of the capacitor 107.

The feedback resistor 103 has one end connected to the output terminal of the first operational amplifier 110, and has the other end connected to one end of the resistor 101. The resistor 104 has one end connected to the non-inverting input terminal of the first operational amplifier 110. The resistor 105 has one end connected to the power supply Vcc, and has the other end connected to the other end of the resistor 104.

The resistor 106 has one end connected to the connection point between the resistors 104 and 105, and has the other end grounded. The capacitor 107 has one end grounded, and has the other end connected to the other end of the resistor 101.

The capacitor 108 has one end connected to the first non-inverting input terminal IN1, and has the other end connected to the other end of the resistor 104. The capacitor 109 is connected in parallel with the resistor 106. The first operational amplifier 110 has one power supply terminal connected to power supply Vcc, and has the other power supply terminal grounded.

In the configuration described above, the resistors 105 and 106 function as a voltage dividing resistor, dividing the voltage of the power supply Vcc and outputting the divided voltage as a reference voltage VREF1 via the resistor 104 to the non-inverting input terminal of the first operational amplifier 110.

The resistors 104, 105, and 106 and the capacitor 109 function as a first-order low-pass filter, preventing high-frequency noise of the reference voltage VREF1 from being input to the first operational amplifier 110.

The second operational amplifier section 42 includes a resistor 201, a feedback resistor 203, a resistor 204, a resistor 205, a resistor 206, a capacitor 207, a capacitor 208, a capacitor 209, and a second operational amplifier 210. The resistor 201 has one end connected to an inverting input terminal of the second operational amplifier 210, and has the other end connected to one end of the capacitor 207.

The feedback resistor 203 has one end connected to an output terminal of the second operational amplifier 210, and has the other end connected to one end of the resistor 201. The resistor 204 has one end connected to the non-inverting input terminal of the second operational amplifier 210. The resistor 205 has one end connected to the power supply Vcc, and has the other end connected to the other end of the resistor 204.

The resistor 206 has one end connected to the connection point between the resistors 204 and 205, and has the other end grounded. The capacitor 207 has one end grounded, and has the other end connected to the other end of the resistor 201.

The capacitor 208 has one end connected to the second non-inverting input terminal IN2, and has the other end connected to the other end of the resistor 204. The capacitor 209 is connected in parallel with the resistor 206. The second operational amplifier 210 has one power supply terminal connected to the power supply Vcc, and has the other power supply terminal grounded.

In the configuration described above, the resistors 205 and 206 function as a voltage dividing resistor, dividing the voltage of the power supply Vcc and outputting the divided voltage as a reference voltage VREF2 via the resistor 204 to the non-inverting input terminal of the second operational amplifier 210.

Moreover, the resistors 204, 205, and 206 and the capacitor 209 function as a first-order low-pass filter, preventing high-frequency noise of the reference voltage VREF2 from being input to the second operational amplifier 210.

The third operational amplifier section 43 includes a resistor 301, a feedback resistor 303, a resistor 304, a resistor 305, a resistor 306, a capacitor 307, a capacitor 308, a capacitor 309 and a third operational amplifier 310. The resistor 301 has one end connected to an inverting input terminal of the third operational amplifier 310, and has the other end connected to one end of the capacitor 307.

The feedback resistor 303 has one end connected to an output terminal of the third operational amplifier 310, and has the other end connected to one end of the resistor 301. The resistor 304 has one end connected to the non-inverting input terminal of the third operational amplifier 310. The resistor 305 has one end connected to the power supply Vcc, and has the other end connected to the other end of the resistor 304.

The resistor 306 has one end connected to the connection point between the resistors 304 and 305, and has the other end grounded. The capacitor 307 has one end grounded, and has the other end connected to the other end of the resistor 301.

The capacitor 308 has one end connected to the third inverting input terminal IN3, and has the other end connected to the other end of the resistor 304. The capacitor 309 is connected in parallel with the resistor 306. The third operational amplifier 310 has a power supply terminal connected to the power supply Vcc, and has the other power supply terminal grounded.

In the configuration described above, the resistors 305 and 306 function as a voltage dividing resistor, dividing the voltage of the power supply Vcc and outputting the divided voltage as a reference voltage VREF3 via the resistor 304 to the non-inverting input terminal of the third operational amplifier 310.

Moreover, the resistors 304, 305, and 306 and the capacitor 309 function as a first-order low-pass filter, preventing high-frequency noise of the reference voltage VREF3 from being input to the third operational amplifier 310.

The fourth operational amplifier section 44 includes a resistor 401, a feedback resistor 403, a resistor 404, a resistor 405, a resistor 406, a capacitor 407, a capacitor 408, a capacitor 409, and a fourth operational amplifier 410. The resistor 401 has one end connected to an inverting input terminal of the fourth operational amplifier 410, and has the other end connected to one end of the capacitor 407.

The feedback resistor 403 has one end connected to an output terminal of the fourth operational amplifier 410, and has the other end connected to one end of the resistor 401. The resistor 404 has one end connected to the non-inverting input terminal of the fourth operational amplifier 410. The resistor 405 has one end connected to the power supply Vcc, and has the other end connected to the other end of the resistor 404.

The resistor 406 has one end connected to the connection point between the resistors 404 and 405, and has the other end grounded. The capacitor 407 has one end grounded, and has the other end connected to the other end of the resistor 401.

The capacitor 408 has one end connected to the fourth non-inverting input terminal IN4, and has the other end connected to the other end of the resistor 404. The capacitor 409 is connected in parallel with the resistor 406. The fourth operational amplifier 410 has one power supply terminal connected to the power supply Vcc, and has the other power supply terminal grounded.

In the configuration described above, the resistors 405 and 406 function as voltage dividing resistors, dividing the voltage of the power supply Vcc and outputting the divided voltage as a reference voltage VREF4 via the resistor 404 to the non-inverting input terminal of the fourth operational amplifier 410.

Moreover, the resistors 404, 405, and 406 and the capacitor 409 function as a first-order low-pass filter, preventing high-frequency noise of the reference voltage VREF4 from being input to the fourth operational amplifier 410.

In the configuration described above, as in the eleventh embodiment, the reference voltage VREF1 and the reference voltages VREF2 to VREF4 are mutually uncorrelated, and the reference voltages VREF2 to VREF4 are not affected by the reference voltage VREF1.

Therefore, even if an input of −18.5 dBV is applied to the first non-inverting input terminal IN1 of the first operational amplifier 110, the input signal at the first non-inverting input terminal IN1 is not output to the reference voltages VREF2 to VREF4. The output levels of the reference voltages VREF2 to VREF4 due to the input at the first non-inverting input terminal IN1 remain at −∞.

For similar reasons, no crosstalk occurs among the non-inverting inputs of the first operational amplifier 110, the second operational amplifier 210, the third operational amplifier 310, and the fourth operational amplifier 410. As described above, according to the twelfth embodiment, each channel corresponding to each of the first operational amplifier 110, the second operational amplifier 210, the third operational amplifier 310, and the fourth operational amplifier 410 (e.g., audio channel) is separated, and the corresponding reference voltages VREF1 to VREF4 are mutually uncorrelated. Therefore, crosstalk does not occur.

As described above, according to each embodiment, it is possible to reduce crosstalk between the operational amplifiers and perform signal amplification in an operational amplifier circuit having plural operational amplifier sections each having an operational amplifier driven by a single power supply.

Although specific applications of the operational amplifier circuit have not been described, for example, a differential-output microphone is connected to the input terminal of a differential input operational amplifier, and a single-ended output microphone is connected to the input terminal of a non-inverting input operational amplifier. Therefore, it is possible to suppress distortion caused by crosstalk between the output signals of the respective microphones and achieve high channel separation in signal transmission.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An operational amplifier circuit comprising:
a reference voltage generation circuit connected to a single power supply, the reference voltage generation circuit being configured to generate a reference voltage signal and output the reference voltage signal; and
a plurality of operational amplifier circuit sections, each section including an operational amplifier operating with the single power supply, wherein
an output impedance of the reference voltage generation circuit is set to cause a voltage fluctuation amount of the reference voltage signal to be equal to or less than a predetermined value.

2. The operational amplifier circuit according to claim 1, wherein the reference voltage generation circuit includes a Zener diode connected in a reverse-biased state between the reference voltage generation circuit and ground.

3. The operational amplifier circuit according to claim 1, wherein the reference voltage generation circuit includes:
a voltage divider circuit configured to divide a voltage of the single power supply; and
an emitter follower circuit configured to receive an output voltage of the voltage divider circuit via a control terminal of the emitter follower circuit and generate the reference voltage signal.

4. The operational amplifier circuit according to claim 1, wherein the reference voltage generation circuit includes:
a voltage divider circuit configured to divide a voltage of the single power supply; and
an operational amplifier configured to receive an output voltage of the voltage divider circuit via an input terminal of the operational amplifier and generate the reference voltage signal.

5. The operational amplifier circuit according to claim 1, wherein the operational amplifier is configured as a differential input operational amplifier.

6. The operational amplifier circuit according to claim 1, wherein the operational amplifier is configured as a non-inverting input operational amplifier.

7. The operational amplifier circuit according to claim 1, further comprising a low-pass filter configured to remove a high-frequency component from an output of the reference voltage generation circuit and supply the filtered output to the operational amplifier.

8. An operational amplifier circuit comprising:
a plurality of reference voltage generation circuits connected to a single power supply, each of the reference voltage generation circuits being configured to generate and output a reference voltage signal; and
a plurality of operational amplifier circuit sections, each section including an operational amplifier configured to operate with the single power supply, wherein
the reference voltage generation circuits are each connected to a non-inverting input of one of the operational amplifier circuit sections in a one-to-one correspondence.

9. The operational amplifier circuit according to claim 8, wherein the reference voltage generation circuit includes:
a voltage divider circuit configured to divide a voltage of the single power supply; and
a low-pass filter configured to remove a predetermined high-frequency component from an output voltage of the voltage divider circuit.

10. The operational amplifier circuit according to claim 8, wherein the operational amplifier is configured as a differential input operational amplifier.

11. The operational amplifier circuit according to claim 8, wherein the operational amplifier is configured as a non-inverting input operational amplifier.
